(19) United States
(12) Patent Application Publication
(10) Pub. No.: US 2010/0044752 A1
(43) Pub. Date: Feb. 25, 2010

(54) Semiconductor device and manufacturing method

(75) Inventor: Toshiharu Marui, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/453,969

(22) Filed: May 28, 2009

(30) Foreign Application Priority Data
Aug. 22, 2008 (JP) 2008-214437

(51) Int. Cl. H01L 29/778; H01L 21/335

(52) U.S. Cl. 257/192; 438/172; 257/E29.246; 257/E21.403

(57) ABSTRACT

A metal-insulator-semiconductor high electron mobility transistor (MIS-HEMT) has a substrate in which an electron supply layer is interposed between an electron channel layer and the surface of the substrate. A pair of main electrodes are formed on the surface of the substrate. A recess is formed in the surface of the substrate between the main electrodes. A gate insulation film is formed on the surface of the substrate, at least between the first and second main electrodes, covering the inside walls and floor of the recess. A gate electrode is formed on the gate insulation film, filling in the recess. The gate insulation film has a crystal density of at least 2.9 g/cm³, which mitigates the reduction in threshold voltage caused by the recess.

### BACKGROUND OF THE INVENTION

1. Field of the Invention

The present invention relates to a semiconductor device and a method of manufacturing it, more particularly to a high electron mobility transistor having a metal-insulator-semiconductor structure and a method of manufacturing it.

2. Description of the Related Art

A high electron mobility transistor (HEMT) is a type of field-effect transistor in which current flows in a two-dimensional electron gas (2DEG). One known HEMT structure has a substrate including an undoped gallium nitride (GaN) electron channel layer and an aluminum gallium nitride (AlGaN) electron supply layer. The source, drain, and gate electrodes are disposed on the surface of the AlGaN electron supply layer. A 2DEG layer forms within the electron channel layer by piezo polarization and/or spontaneous polarization of the heterojunction interface between the electron channel layer and the electron supply layer. The electron supply layer has low resistance in its thickness direction and high resistance in the transverse direction, so current flowing between the source and drain electrodes moves in the 2DEG layer. HEMTs of this type combine high switching speeds with high-temperature and high-power operating capabilities, making them promising candidates for high-performance electronic devices.

Recently, metal-insulator-semiconductor (MIS) HEMTs have been drawing attention. In a MIS-HEMT, the gate electrode is separated from the substrate by a thin gate insulation film, as described by Kanamura et al. in IEICE Technical Report ED2006-236, MW2006-189 (2007-1). As compared with metal-semiconductor (MES) HEMTs, in which the gate electrode forms a Schottky junction with the surface of the substrate, the advantages of MIS-HEMTs are that the gate leakage current is greatly reduced and the voltage between the gate and substrate can be forward-biased.

Because of the gate insulation film, however, the gate electrode is farther from the 2DEG layer in a MIS-HEMT than in a MES-HEMTs. This enlarged separation reduces the transconductance of MIS-HEMTs as compared with MES-HEMTs.

In Japanese Patent Application Publication No. 2005-260172, Kanda et al. have shown that the reduction in transconductance can be mitigated by forming the gate insulation film and the gate electrode of a MIS-HEMT in a recess in the surface of the substrate. Since the bottom of the recess is closer than the surface of the substrate to the 2DEG layer, the distance from the gate electrode to the 2DEG layer is reduced, so that the presence of the gate insulation film does not reduce the transconductance as much.

The presence of a gate insulation film between the substrate and the gate electrode, however, also reduces the threshold voltage of a MIS-HEMT as compared to a MES-HEMT.

The amount by which the threshold voltage is reduced by the formation of the gate insulation film depends on the material properties of the gate insulation film. More specifically, the dielectric constant of, for example, a silicon nitride film is known to be proportionally related to the crystal density of the film; as the crystal density decreases, the dielectric constant of the film decreases. Accordingly, a silicon nitride gate insulation film with a low crystal density can significantly lower the threshold voltage of a field-effect transistor.

Kanda et al. do not suggest how the threshold voltage of a MIS-HEMT having a recessed gate structure might be controlled, and say nothing about the relation of the crystal density of the gate insulation film to the threshold voltage.

### SUMMARY OF THE INVENTION

An object of the present invention is to provide the gate insulation film in a MIS-HEMT having a recessed structure with a crystal density that mitigates the reduction in threshold voltage caused by the gate insulation film.

The inventors have found that the reduction in the threshold voltage of a MIS-HEMT can be mitigated by forming the gate insulation film so as to have an appropriate crystal density. An MIS-HEMT according to the invention has the following characteristics.

The MIS-HEMT comprises a substrate having an electron channel layer and an electron supply layer, the electron supply layer being disposed between the electron channel layer and a major surface of the substrate. A recess is formed in the major surface. A first main electrode and a second main electrode are formed on opposite sides of the recess on the major surface.

A gate insulation film is formed, covering the floor of the recess, the inside walls of the recess, and the surface of the substrate in the region between the first and second main electrodes. The gate insulation film is thinner than the depth of the recess and has a crystal density of at least 2.9 g/cm³.

A gate electrode is formed on the gate insulation film, filling in the recess.

This type of MIS-HEMT can be manufactured by the following four steps.

In the first step, the recess is formed in the surface of the substrate.

In the second step, the gate insulation film is formed by thermal chemical vapor deposition. The deposition process is controlled so that the resulting gate insulation film is thinner than the depth of the recess and has a crystal density of at least 2.9 g/cm³. At this stage the gate insulation film covers the entire surface of the substrate, including the floor and inside walls of the recess.

In the third step, the gate insulation film is partially removed to expose the surface of the substrate in two areas on opposite sides of the recess. The first and second main electrodes are then formed on the surface of the substrate in these exposed areas, facing each other across the recess.

In the fourth step, the gate electrode is formed, filling in the recess.

The use of thermal chemical vapor deposition creates a gate insulation film having a crystal density of at least 2.9 g/cm³.

The crystal density of at least 2.9 g/cm³ mitigates the reduction in threshold voltage caused by the gate insulation film.

These results have been confirmed through experiments, as described in detail below.

### BRIEF DESCRIPTION OF THE DRAWINGS

In the attached drawings:

FIGS. 1, 2, 3, 4, and 5 are schematic sectional views illustrating steps in the fabrication of a MIS-HEMT according to the present invention;

FIG. 6 is a graph of simulated and measured results of an x-ray reflectometry experiment for evaluating the gate insulation film of a MIS-HEMT manufactured as in FIGS. 1 to 5;

FIG. 7 is a graph illustrating the drain current characteristic of a MIS-HEMT with a gate insulation film formed by thermal chemical vapor deposition;

FIG. 8 is a graph illustrating the drain current characteristic of a MIS-HEMT with a gate insulation film formed by plasma chemical vapor deposition; and

FIG. 9 is a graph illustrating the drain current characteristic a MES-HEMT.

### DETAILED DESCRIPTION OF THE INVENTION

A MIS-HEMT and fabrication method embodying the present invention, will now be described with reference to the attached non-limiting drawings, in which like elements are indicated by like reference characters.

The inventive MIS-HEMT has the structure summarized above, the gate electrode being formed on a gate insulation film having a crystal density of at least 2.9 g/cm³, in a recess on the surface of the substrate. The inventive MIS-HEMT fabrication method includes the following four steps.

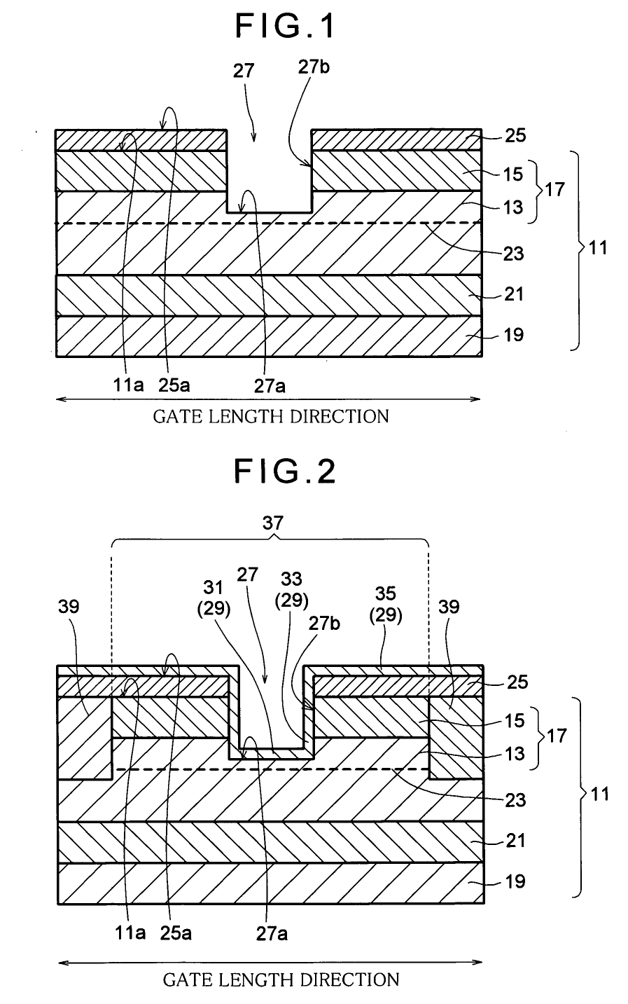

In the first step, a recess 27 is formed on a major surface 11a of a substrate 11 to obtain the structure shown in FIG. 1. The substrate 11 includes a layered active structure 17 formed on a base layer 19. The layered active structure 17 includes the electron channel layer and electron supply layer.

The substrate of the MIS-HEMT may in general be a silicon substrate, a silicon-on-insulator (SOI) substrate, or a semiconductor substrate of various other known types, as called for by design requirements. In the description below, the substrate 11 is a heterojunction substrate having an AlGaN layer formed on a GaN layer.

As shown in FIG. 1, the substrate 11 includes the base layer 19, a buffer layer 21, an un-intentionally-doped (UID) GaN layer 13, and a UID AlGaN layer 15. For simplicity, the UID notation will be omitted in referring to the GaN layer 13 and AlGaN layer 15 below. The base layer 19 is formed from sapphire or another appropriate material. The buffer layer 21 is a layer of aluminum nitride (AlN), GaN, or another appropriate material formed on the base layer 19 by metalorganic chemical vapor deposition (MOCVD). The GaN layer 13, which is formed on the buffer layer 21, functions as the electron channel layer; the AlGaN layer 15, which is formed on the GaN layer 13, functions as the electron supply layer. The GaN layer 13 and AlGaN layer 15 may be formed by MOCVD or molecular beam epitaxy (MBE). In the layered active structure 17, the energy bandgap difference between the GaN layer 13 and AlGaN layer 15 causes a two-dimensional electron gas (2DEG) layer 23 to form in the GaN layer 13 near the interface with the AlGaN layer 15.

The first step begins with the formation of a passivation film 25 on the major surface 11a of the substrate 11 to protect the substrate from contamination during the fabrication process. The passivation film 25 is preferably formed by growing a silicon nitride film by thermal chemical vapor deposition (CVD).

If a field plate will be formed above the substrate 11 in a later step, the thickness of the passivation film 25 can be adjusted to adjust the distance from the field plate to the major surface 11a. In this case the thickness of passivation film 25 is controlled according to the desired distance from the field plate to the major surface 11a. The preferred thickness will be described later.

The recess 27 is formed after the passivation film 25 is formed. The recess 27 is formed by well-known photolithography and dry etching techniques employing, for example, inductively coupled plasma ion etching. The recess 27 extends through the passivation film 25 and into the substrate 11 below. The depth of the recess 27 affects both the transconductance and the threshold voltage of the fabricated MIS-HEMT. The depth should be selected so as not to produce a threshold voltage of zero volts (0 V), but so as to mitigate the reduction in transconductance due to the gate insulation film. Specifically, the recess 27 should have a depth such that the distance from the floor 27a of the recess 27 to the 2DEG layer 23 becomes, for example, about five to six nanometers (5 nm to 6 nm).

In this embodiment, the MIS-HEMT is fabricated as a normally-on device in which current flows unless a negative voltage is applied to the gate electrode. In this case, the recess 27 should have a depth such that the floor 27a of the recess 27 is located at the 2DEG layer 23, or at most 3 nm to 5 nm above the 2DEG layer 23.

Since the passivation film 25 is removed from the recess 27, the surface of the substrate 11 is partially exposed within the recess 27. This exposed surface, including the floor 27a and inside walls 27b of the recess 27, is vulnerable to contamination by oxides, carbon compounds, and other contaminants in the air. If such contaminants become attached to the inside of the recess 27, they will remain after the gate electrode is formed in the recess 27 and may degrade the characteristics of the fabricated MIS-HEMT.

Accordingly, after the recess 27 is formed in the first step, before the second step, contaminants such as oxides, carbon compounds, and other chemicals are removed from the inside of the recess 27 by cleaning with ammonia (NH₃) at a high temperature such as, for example, about 800° C. The second step should be performed promptly after the cleaning. After the second step, the gate insulation film formed in the second step protects the floor 27a and inside walls 27b of the recess 27 from contamination.

In the second step, a gate insulation film 29 is formed to obtain the structure shown in FIG. 2. The gate insulation film 29 is thinner than the depth of the recess 27 and is formed so as to cover the entire surface of the substrate 11, including the recess 27. The gate insulation film 29 includes a first insulating region 31 covering the floor 27a of the recess 27, a second insulating region 33 covering the inside walls 27b of the recess 27, and a third insulating region 35 covering the rest of the major surface 11a of the substrate 11. These three regions 31, 33, 35 are contiguous and are formed integrally at the same time. The third insulating region 35 is formed on the upper surface 25a of the passivation film 25, so the passivation film 25 is sandwiched between the third insulating region 35 and the substrate 11.

Th gate insulation film 29 in this embodiment is formed so as to have a crystal density that mitigates the reduction in the threshold voltage of the MIS-HEMT. As noted above, the threshold voltage drops significantly as the crystal density of the gate insulation film decreases. Accordingly, in this embodiment, the gate insulation film 29 is formed so as to have a comparatively high crystal density, more specifically, a crystal density of at least 2.9 g/cm³. To obtain this density, a silicon nitride film approximately 5 nm thick is formed by thermal CVD at a pressure of 760 Torr. The reactive gases are 0.7% silane (SiH₄) at a flow rate of one hundred standard centimeters per minute (100 sccm) and 100% ammonia (NH₃) at a flow rate of six liters per minute (6 slm). The carrier gas is a mixture of nitrogen (N₂) and hydrogen (H₂).

In the second step, isolation regions are also formed in the substrate 11 in order to isolate device regions 37 from each other, by implanting, for example, argon (Ar) ions or other ions into the substrate 11. In this case, to electrically isolate the device regions 37 reliably, ions are implanted from the major surface 11a to a level below the 2DEG layer 23 to form the isolation regions 39. The isolation regions 39 may be formed either before or after the formation of the gate insulation film 29.

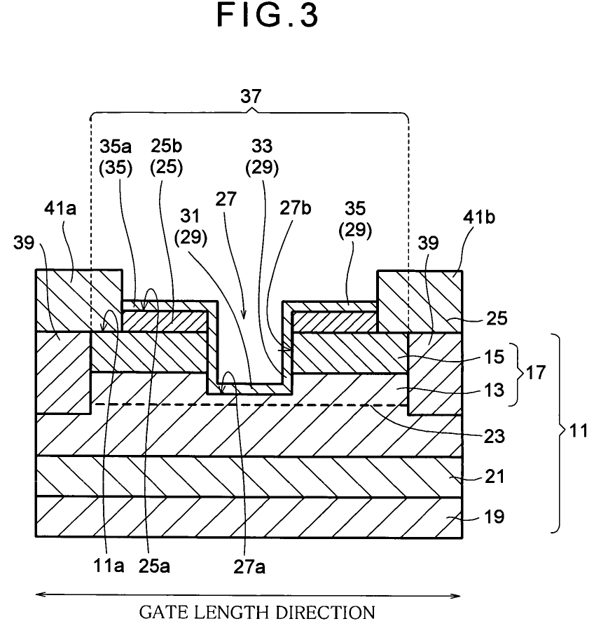

In the third step, a first main electrode 41a and a second main electrode 41b are formed to obtain the structure shown in FIG. 3.

To obtain this structure, the gate insulation film 29 and passivation film 25 are selectively removed from two areas outside the recess 27, on opposite sides of the recess 27. The selective removal may be effected by photolithography and etching. Either wet etching or dry etching, e.g., reactive ion etching, may be used. The etching process proceeds continuously through the gate insulation film 29 and passivation film 25 until the major surface 11a of the substrate 11 is exposed. The remaining parts of the passivation film 25 and the third insulating region 35 of the gate insulation film 29 are indicated by respective reference characters 25b and 35a in FIG. 3.

Next, the first main electrode 41a and second main electrode 41b are formed on the exposed parts of the major surface 11a of the substrate 11, preferably by electron beam (EB) deposition of, for example, titanium (Ti) and aluminum (Al). The main electrodes 41a, 41b are in ohmic contact with the major surface 11a, enabling one of the main electrodes 41a, 41b to function as a source electrode and the other to function as a drain electrode.

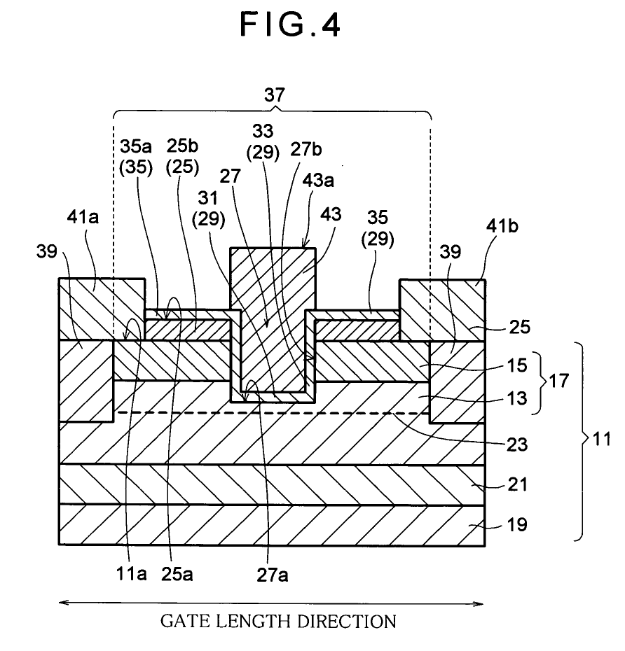

In the fourth step, a gate electrode 43 is formed on the gate insulation film 29 between the first and second main electrodes 41a, 41b, filling in the recess 27, to obtain the structure shown in FIG. 4. The gate electrode 43 and is formed by EB deposition of, for example, nickel (Ni) and gold (Au).

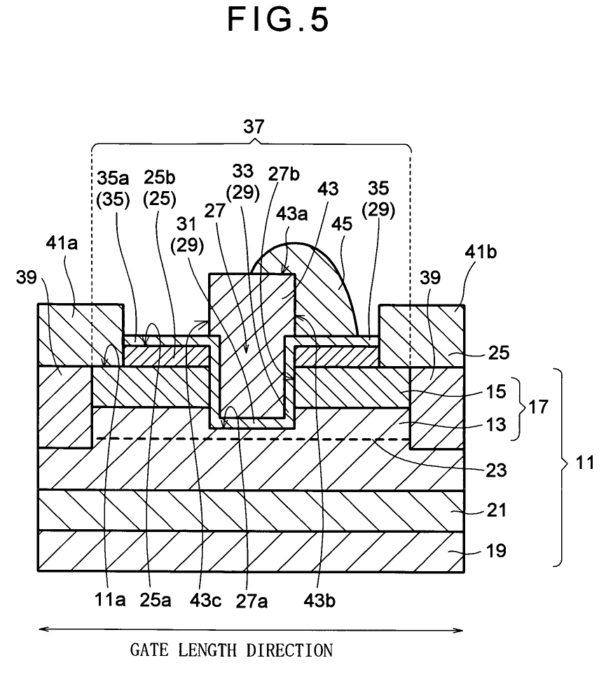

After the fourth step, a field plate 45 may be formed as shown in FIG. 5. The purpose of the field plate 45 is to reduce current collapse by reducing the field concentration at the periphery of the gate electrode 43.

The field plate 45 in FIG. 5 partially covers the upper surface 43a of the gate electrode 43, one of the side surfaces 43b, 43c of the gate electrode 43 in the gate length direction (indicated by a double-headed arrow in FIG. 5), and the third insulating region 35 on this side.

During the operation of a HEMT, electric field concentrations tend to occur in the region between the gate electrode and the drain electrode, so the field plate 45 is preferably formed on the side of the gate electrode that faces the drain electrode. If the second main electrode 41b will function as the drain, the field plate should be formed as shown in FIG. 5. If the first main electrode 41a will function as the drain, the field plate 45 should be formed to cover the side surface 43c of the gate electrode 43 and at least partially cover the third insulating region 35 of the gate insulation film 29 between the gate electrode 43 and the first main electrode 41a (the left side in the drawing), instead of covering the side surface 43b and the third insulating region 35 on the right side.

To obtain the maximum reduction of the field concentration at the periphery of the gate electrode 43, it is necessary to optimize the distance from the field plate 45 to the major surface 11a. This distance is equal to the combined thickness of the passivation film 25 formed in the first step and the third insulating region 35 of the gate insulation film 29. The combined thickness should be at least 50 nm. If the third insulating region 35 of the gate insulation film 29 has a thickness of 5 nm, accordingly, the passivation film 25 may be as little as 45 nm thick. The combined thickness is more preferably about 150 nm, however, so if the third insulating region 35 is 5 nm thick, the passivation film 25 is preferably about 145 nm thick.

In this embodiment, the field plate 45 is formed by, for example, EB deposition of titanium (Ti), platinum (Pt), and gold (Au).

By using thermal CVD, the fabrication process described above produces a gate insulation film 29 having a crystal density of at least 2.9 g/cm³, which is higher than the crystal density of silicon nitride films formed by conventional methods such as plasma CVD. As noted above, the dielectric constant of the gate insulation film 29 is proportional to its crystal density, so the use of thermal CVD in this embodiment has the effect of increasing the dielectric constant of the gate insulation film 29.

In addition, the gate electrode 43 is formed in the recess 27, which mitigates the decrease in transconductance caused by the MIS structure. Thus the adverse effects of the gate insulation film on both the threshold voltage and the transconductance of the HEMT are reduced.

X-ray reflectometry (XRR) measurements and a simulation were carried out to confirm that a gate insulation film having a crystal density of 2.9 g/cm³ or more can be formed by thermal CVD under the conditions described in the second step above.

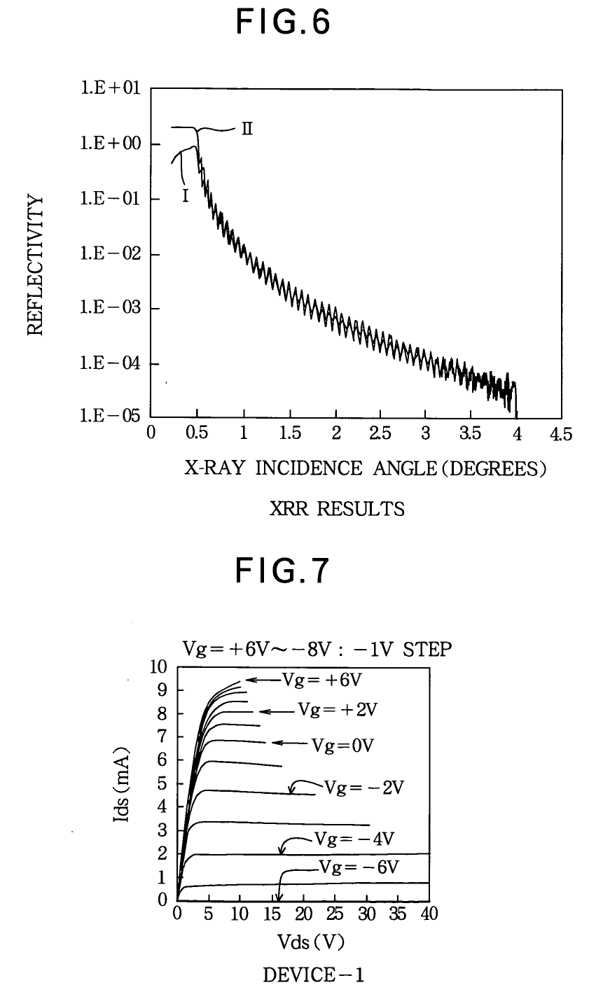

FIG. 6 is a graph showing the measured and simulated XRR results. The horizontal axis represents the angle of x-ray incidence in degrees; the vertical axis represents the reflected x-ray intensity expressed as a reflectivity value.

Curve I in FIG. 6 shows reflectivity values obtained by measuring a MIS-HEMT fabricated according to this embodiment. Curve II in FIG. 6 shows theoretical reflectivity values obtained by simulation, using commercially available DIFFRACplus LEPTOS simulation software. To calculate the crystal density of the gate insulation film, the crystal density parameter of curve II was varied, the value that made curve II fit curve I was determined, and this value was taken as the crystal density of the gate insulation film. The results showed that the crystal density of the gate insulation film formed by thermal CVD under the conditions described in the second step was 2.93 g/cm³.

The above results demonstrate that a MIS-HEMT with a gate insulation film having a crystal density of at least 2.9 g/cm³ can be obtained by forming the gate insulation film by thermal CVD.

To evaluate the effect of forming a gate insulation film having a high crystal density, experiments were conducted to measure the characteristics of MIS-HEMTs fabricated by the above method and other methods.

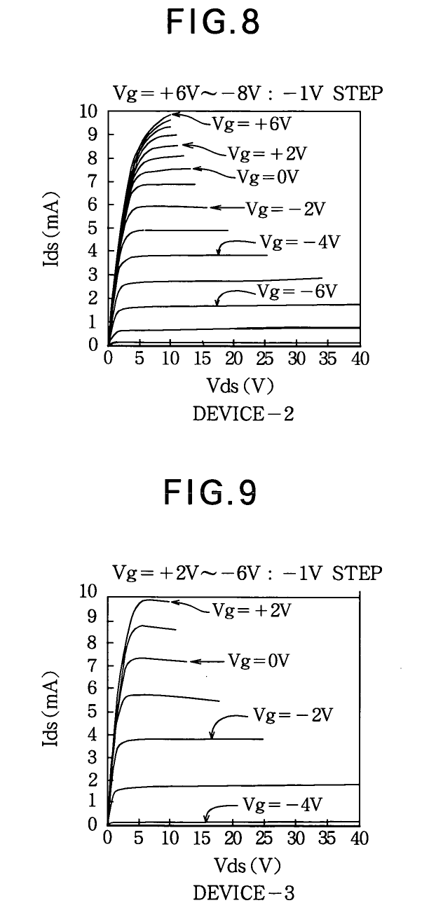

FIGS. 7 to 9 show the results obtained. In each case the drain current was measured as a function of the drain-source voltage for various applied gate voltages. FIG. 7 shows results obtained from a MIS-HEMT device (referred to below as device-1) fabricated according to this embodiment, with a gate insulation film formed by thermal CVD, having a crystal density of 2.93 g/cm³. FIG. 8 shows results obtained from a similar MIS-HEMT device (referred to below as device-2) having a gate insulation film formed by plasma CVD, which produces a lower crystal density than thermal CVD. FIG. 9 shows results obtained from a MES-HEMT device (referred to below as device-3) without a gate insulation film. In each graph the vertical axis represents drain-source current (Ids) in milliamperes and the horizontal axis represents drain-source voltage (Vds) in volts.

The measurements were made by applying a pulsed measurement voltage. The data in FIGS. 7 and 8 were taken with gate voltages (Vg) ranging from six volts to minus eight volts (+6 V to −8 V) in steps of one volt. The data in FIG. 9 were taken with gate voltages (Vg) ranging from two volts to minus six volts (+2 V to −6 V) in steps of one volt.

The only structural difference between device-1 and device-2 was the crystal density of the gate insulation films. The only difference between device-2 and device-3 was the presence or absence of a gate insulation film. Aside from these differences, the measurements were performed under identical conditions. The gate insulation film thickness of device-1 and device-2 was 10 nm.

From the data in FIGS. 7, 8, and 9, device-1 was determined to have a threshold voltage of about −5.83 V, device-2 to have a threshold voltage of about −7.33 V, and device-3 to have a threshold voltage of about −4.35 V.

A comparison of these measured threshold voltages shows that in the MIS-HEMT structure fabricated according to this embodiment with a thermal CVD gate insulation film (device-1), the threshold voltage is reduced by approximately one volt (1 V) with respect to a comparable MES-HEMT structure without a gate insulation film (device-3).

In the MIS-HEMT structure with a gate insulation film formed by plasma CVD (device-2), the threshold voltage was reduced by three volts (3 V) as compared with the comparable MES-HEMT structure (device-3).

This demonstrates that the use of thermal CVD to form the gate insulation film in a MIS-HEMT with a recessed gate mitigates the reduction in threshold voltage, as compared with forming the gate insulation film by thermal CVD.

Combining the result of this experiment with the result of the x-ray reflectometry experiment in FIG. 6 shows that the mitigation effect is obtained if the crystal density of the gate insulation film is 2.9 g/cm³ or more.

The invention is not limited to the embodiment described above. Those skilled in the art will recognize that numerous variations are possible within the scope of the invention, which is defined in the appended claims.

What is claimed is:

1. A semiconductor device comprising:
a substrate having a major surface, an electron channel layer, an electron supply layer disposed between the electron channel layer and the major surface, and a recess formed in the major surface, the recess having a floor, inside walls, and a depth, the depth being from the major surface to the floor;
a first main electrode and a second main electrode disposed on the major surface of the substrate on mutually opposite sides of the recess;
a gate insulation film including a first insulating region covering the floor of the recess, a second insulating region covering the inside walls of the recess, and a third insulating region covering the major surface of the substrate at least between the first and second main electrodes outside the recess, the first, second, and third insulating regions being contiguous, the gate insulation film being thinner than the depth of the recess; and
a gate electrode formed on the gate insulation film, filling in the recess, the gate electrode having an upper surface, a side surface facing the first main electrode, and a side surface facing the second main electrode;
wherein the gate insulation film has a crystal density of at least 2.9 g/cm³.

2. The semiconductor device of claim 1, wherein a two-dimensional electron gas layer is formed in the electron channel layer and the floor of the recess is located at the two-dimensional electron gas layer.

3. The semiconductor device of claim 1, wherein a two-dimensional electron gas layer is formed in the electron channel layer and the floor of the recess is located at most five nanometers from the two-dimensional electron gas layer.

4. The semiconductor device of claim 1, further comprising a passivation film disposed between the substrate and the third insulating region of the gate insulation film.

5. The semiconductor device of claim 4, wherein the third insulating region of the gate insulation film and the passivation film have a combined thickness of one hundred fifty nanometers.

6. The semiconductor device of claim 4, further comprising a field plate at least partially covering the upper surface of the gate electrode, the side surface of the gate electrode facing the second main electrode, and the third insulating region of the gate insulation film between the gate electrode and the second main electrode.

7. A method of manufacturing a semiconductor device, comprising:
forming a recess in a major surface of a substrate having an electron channel layer and an electron supply layer, the electron supply layer being disposed between the electron channel layer and the major surface, the recess having a floor, inside walls, and a depth measured from the major surface to the floor;
forming a gate insulation film on the major surface of the substrate by thermal chemical vapor deposition, the gate insulation film including a first insulating region covering the floor of the recess, a second insulating region covering the inside walls of the recess, and a third insulating region covering the major surface of the substrate outside the recess, the gate insulation film being thinner than the depth of the recess, the gate insulation film having a crystal density of at least 2.9 g/cm³;
removing part of the third insulating region of the gate insulation film on mutually opposite sides of the recess to expose the major surface of the substrate;
forming first and second main electrodes on the major surface of the substrate where thus exposed; and
forming the gate electrode on the gate insulation film, the gate electrode filling in the recess.

8. The method of claim 7, wherein a two-dimensional electron gas layer is formed in the electron channel layer and the floor of the recess is located at the two-dimensional electron gas layer.

9. The method of claim 7, wherein a two-dimensional electron gas layer is formed in the electron channel layer and the floor of the recess is located at most five nanometers from the two-dimensional electron gas layer.

10. The method of claim 7, further comprising forming a passivation film on the major surface of the substrate before forming the recess, wherein forming the recess includes removing the passivation film from the recess and removing part of the substrate below the passivation layer from the recess, and removing part of the third insulating region of the gate insulation film includes removing part of the passivation film to expose the major surface of the substrate where the first and second main electrodes will be formed.

11. The method of claim 10, wherein the third insulating region of the gate insulation film and the passivation film have a combined thickness of one hundred fifty nanometers.

12. The method of claim 10, wherein the gate electrode has an upper surface, a side surface facing the first main electrode, and a side surface facing the second main electrode, the method further comprising forming a field plate at least partially covering the upper surface of the gate electrode, the side surface of the gate electrode facing the second main electrode, and the third insulating region of the gate insulation film between the gate electrode and the second main electrode.

13. The method of claim 7, further comprising cleaning the floor and the inside walls of the recess before forming the gate insulation film.
